(19) United States
(12) Patent Application Publication
(10) Pub. No.: US 2016/0068943 A1
(43) Pub. Date: Mar. 10, 2016

(54) SPUTTERING TARGET OF MULTI-COMPONENT SINGLE BODY AND METHOD FOR PREPARATION THEREOF, AND METHOD FOR PRODUCING MULTI-COMPONENT ALLOY-BASED NANOSTRUCTURED THIN FILMS USING SAME

(71) Applicant: KOREA INSTITUTE OF INDUSTRIAL TECHNOLOGY, Chungcheongnam-do (KR)

(72) Inventors: Seung Yong SHIN, Seoul (KR); Kyoung Il MOON, Incheon (KR); Ju Hyun SUN, Incheon (KR); Chang Hun LEE, Incheon (KR); Jung Chan BAE, Gyeonggi-do (KR)

(73) Assignee: KOREA INSTITUTE OF INDUSTRIAL TECHNOLOGY, Chungcheongnam-do (KR)

(21) Appl. No.: 14/924,769

(22) Filed: Oct. 28, 2015

Related U.S. Application Data
(62) Division of application No. 13/510,708, filed on May 18, 2012.

(30) Foreign Application Priority Data
Nov. 19, 2009 (KR) 10-2009-0112258
Nov. 9, 2010 (KR) 10-2010-0111197

(51) Int. Cl. C23C 14/00; B22D 7/00; C22C 45/10; B22D 21/00; C23C 14/34

(52) U.S. Cl. CPC C23C 14/0036; B22D 21/00; C23C 14/3414; C22C 45/10; B22D 7/005

(57) ABSTRACT

The present invention relates to a sputtering target of a multi-component single body, a preparation method thereof, and a method for fabricating a multi-component alloy-based nanostructured thin film using the same. The sputtering target according to the present invention comprises an amorphous or partially crystallized glass-forming alloy system composed of a nitride forming metal element, which is capable of reacting with nitrogen to form a nitride, and a non-nitride forming element which has no or low solid solubility in the nitride forming metal element and does not react with nitrogen or has low reactivity with nitrogen, wherein the nitrogen forming metal element comprises at least one element selected from Ti, Zr, Hf, V, Nb, Ta, Cr, Y, Mo, W, Al, and Si, and the non-nitride forming element comprises at least one element selected from Mg, Ca, Sc, Ni, Cu, Ag, In, Sn, La, Au, and Pb.

### TECHNICAL FIELD

The present invention relates to a sputtering target of a multi-component single body, a preparation method thereof, and a method for fabricating a multi-component alloy-based nanostructured thin film using the same. More specifically, the present invention relates to a sputtering target of a multi-component single body and a preparation method thereof, in which a thin film capable of satisfying not only high-hardness properties, but also various required properties, including high elasticity (low elastic modulus) and low friction (low friction coefficient), can be formed by selective reactive sputtering using a parent target material of a single body comprising two kinds of metal elements (i.e., a nitride forming metal element and a non-nitride forming metal element), which have different reactivities with nitrogen, and to a method for fabricating a multi-component alloy-based nanostructured thin film using the same.

### BACKGROUND ART

There is increasing interest in the development of new nanostructured coatings. Particularly, there is increasing attention to nanostructured coatings based on ‘ceramic/amorphous’ or ‘ceramic/metal’ nanocomposite phase mixtures which are obtained by plasma-assisted PVD or CVD processes using coating systems having a very low mutual miscibility between the main components of the coating compositions or between the constituent phases.

As these coatings, ceramic nanostructured coatings having a combination of a nano-sized ceramic crystalline phase and a nano-sized amorphous ceramic phase have been studied. As a result, these nanostructured thin films show a very high hardness of 70 GPa or more which is comparable to those of c-BN and diamond, and these thin films also have a high elastic modulus value due to the high hardness thereof. Such properties are attributable to the intrinsic bonding pattern (covalent or ionic bonding) of the ceramic materials. Such two physical properties (hardness and elastic modulus) are theoretically desirable for cutting tool materials.

However, substrates having low strength, low hardness and low elastic modulus characteristics, such as low carbon steel, aluminum or magnesium-based alloys, are used in applications other than cutting tools, for example, automobile and machinery parts and exterior parts of automobile and electronics. Application of ceramic wear-resistant coatings to such substrate materials still involves many problems in terms of coating durability. For this reason, the field and range of application of such ceramic coatings are not expanded, even though the ceramic coatings have excellent hardness.

This problem is attributable to the high elastic modulus of the ceramic nanostructured thin films. In other words, an increase in the hardness of the thin films leads to an increase in the elastic modulus, and an increase in the elastic modulus leads to a decrease in the elastic strain-to-failure of the thin film. Meanwhile, in the case in which a material having low hardness and low elastic modulus properties is used as a substrate, when a local deformation force is externally applied, the blockage of this external force by a hard thin film having a thickness of 10 μm or less will be actually difficult due to the egg shell effect, and the elastic/plastic deformation of the substrate cannot be avoided. If the hard thin film does not accommodate some degree of the elastic/plastic deformation of the substrate, the thin film will be broken due to the inconsistency of interfacial elastic properties between the substrate and the coating. Thus, with respect to the required physical properties of hard thin films which are applied to low hardness/low elastic modulus substrates, it is required to improve the elastic properties of the hard thin film so as to have low elastic modulus, although it is also important to increase the hardness of the thin film. Accordingly, increasing the elastic strain of the thin film can be a method capable of increasing the coating durability.

In the case of hardness among the physical properties of thin films, general tribo-systems excluding tools very rarely require a surface hardness of 2000 Hv (20 GPa). The hardness of an oxide or nitride ceramic thin film which is used as a coating material has 1500-3000 Hv, and a carbide or boride ceramic thin film has a hardness of 2000-3000 Hv. These ceramic coatings are generally originated from sputtering target materials, especially transition metals (Ti, Zr, Mo, Cr, W, V, Al, etc.) which can react with reactive gases such as oxygen, nitrogen or carbon source gas to form high-temperature ceramic compounds. The ceramic coatings are easily prepared from the sputtering target by reactive PVD processes using plasma of a mixed gas of reactive gas and argon gas.

The hardness of the above-described ceramic hard thin film is sufficient for use in the field of general tribo-systems which utilize a low-hardness and low elastic modulus material as a substrate, but the elastic modulus thereof is excessively higher than those of the substrates (e.g., 70 GPa for aluminum alloys and 45 GPa for magnesium alloys). Most refractory ceramics have an elastic modulus of 400-700 GPa. Thus, when a ceramic hard thin film and a nanostructured thin film utilize a low elastic modulus material as a substrate, they will have problems in terms of durability due to the inconsistency of elastic properties between the thin film and the substrate. The ratio of hardness to elastic modulus (H/E) is used as an indicator of the elastic strain-to-failure capability of a coating material, and this parameter essentially indicates the resilience and durability of the coating material.

In order to overcome such problems, many studies have been conducted. In typical studies of these studies, metal-based nanostructured thin films were proposed. Metal-based thin films have excellent durability compared to ceramic thin films, because the difference in mechanical properties (particularly elastic properties) from metal substrates is slight, as experienced in the case of Cr electroplating or the like. In other words, these metal-based thin films exhibit a long elastic strain-to-failure which is absent in ceramics, and these thin films have an excellent ability to accommodate plastic strain, compared to ceramics.

However, the metal-based thin films have excessively low hardness compared to ceramic thin films, and thus the hardness thereof needs to be increased. In one method for increasing the hardness of metal-based thin films, A. Leyland and A. Matthew showed that a coating could be nanostructured by using a coating system comprising a second element having mutual immiscibility with the base element of the coating. Nanostructuring the thin film coating structure can increase both the hardness and durability of the metallic coating by the Hall-Petch effect.

Such technology of nanostructuring metal thin films utilizes the quenching effect of unique thin-film forming methods and vapor phase deposition methods. In other words, when a coating composition system is adjusted so as to have mutual immiscibility between the main elements of these thin films and when the high quenching rate of the thin films is used during plasma PVD deposition, a substitutional or interstitial alloying element can form a supersaturated solid solution in the base metal of the thin film. This supersaturated solid solution can be formed into a nanocrystalline or amorphous phase by short-range phase separation, thereby achieving nanostructures in the metal-based thin film.

Specific examples of this coating system include Cr—N and Mo—N, in which nitrogen forms a solid solution. The content of the nitrogen solid solution in chromium is 4.3 atomic % (at. %) at 1650˜1700° C. and is negligibly small at 1000° C. or below. In the case in which the nitrogen content of a coating is controlled to be lower than the stoichiometric nitrogen content of a β-Cr₂N compound by adjusting the partial pressure of the reactive gas nitrogen when carrying out Cr—N coating by PVD, if the concentration of the interstitial element nitrogen in chromium is low, the constituent phase of the thin film becomes a supersaturated solid solution (α-Cr). Alternatively, if the concentration of the interstitial element nitrogen in chromium is high, the constituent phase is subjected to short-range phase separation into two phases consisting of a supersaturated α-Cr phase and a β-Cr₂N phase. Through the competition of growth between these produced phases, the structure of the thin film changes from a columnar structure to a featureless structure, whereby a Cr—N thin film can be obtained by doping a nitrogen element. This Cr—N thin film shows excellent mechanical and chemical properties resulting from its difference in microstructure, compared to a conventional Cr₂N thin film. This featureless thin film shows a hardness of up to 15 GPa which is higher than the hardness (12 GPa or less) of the supersaturated α-Cr thin film having a lower nitrogen content. This indicates that an increase in the content of the supersaturated nitrogen solid solution in the metallic base film promotes nanostructuring, thereby increasing the hardness of the film. In addition, although this featureless nanostructured thin film shows a hardness level slightly lower than the hardness (20-25 GPa) of the columnar β-Cr₂N thin film containing a stoichiometric amount of nitrogen, the results of a ball impact test indicated that the featureless nanostructured thin film has excellent durability compared to the single ceramic β-Cr₂N thin film, as expected.

With respect to another important benefit resulting from nanostructuring in addition to mechanical properties, this nanostructured nitrogen-doped CrN film is dense without through-coating permeable defects capable of acting as corrosion channels, and thus has increased chemical durability as demonstrated in the results of a corrosion test. As is generally known, nanostructured or amorphous materials or coatings have little or no defects acting as corrosion channels and are dense, and thus can be protected from corrosion channels which cause rapid corrosive propagation, and can be protected from uniform and predictable sacrificial corrosion on the surface.

Since then, methods for fabricating more realizable and stable nanostructured thin films and design criteria for this nanostructured costing system were proposed by A. Leyland and A. Matthew. Specifically, there was proposed a design for a coating system in which more advanced nanostructured thin films can be realized by using a transition metal element, which can react with nitrogen to form a nitride, as a base metal, and adding a nitrogen element together with a non-nitride forming element, which is not soluble or has a very low solubility in the nitride forming metal element and does not react with nitrogen or has low reactivity with nitrogen, as a third alloying element.

According to the report of A. Leyland and A. Matthew, examples of the nitride forming metal element include 11 elements, including group IVb-VIb elements (Ti, Zr, Hf, V, Nb, Ta, Cr, Mo, and W) and group IIIa/VIb elements (Al and Si), and examples of the non-nitride forming element include 12 elements, including Mg, Ca, Sc, Ni, Cu, Y, Ag, In, Sn, La, Au, and Pb. The nitride-forming element elements excluding Al are all refractory elements having a melting point of 1000° C. or higher, and the non-nitride forming elements excluding Sc, Y, Au, Ni and Cu show a low melting point of 1000° C. or lower.

In coating systems, there can be various combinations between the nitride forming base elements and the non-nitride forming alloying elements. However, in order to make nanostructured thin film, these elements should be selected to provide a coating system in which these elements are not mutually immiscible or have a very low mutual miscibility. In order to provide such a low solubility, a combination of different elements should be selected in which the difference in atomic radius between the base element and the alloying element is 14% or more or the preferred crystallographic structures thereof differ from each other. Examples of this system include Cr—N—Cu, Cr—N—Ag, Mo—N—Cu, Mo—N—Ag, and Zr—N—Cu systems.

As is known, adding a substitutional alloying element to thin film can become a very efficient method of nanostructuring the thin film compared to a method dependent on the interstitial alloying element nitrogen, and also has the effect of increasing the durability of the thin film, because the thin film has a high H/E ratio as a result of adding a soft non-nitride forming element which does not react with nitrogen. In addition to this effect of increasing the durability of the thin film, the addition of the soft metal makes it possible to prepare a tribo-system hard thin film.

Mo—N—Cu is known to produce a low-melting-point oxide of Mo—Cu—O in a tribological environment, thereby providing a thin film having low friction properties in addition to high hardness and durability characteristics. In a mechanism for producing this low-melting-point/low-friction oxide, when two specific oxides obtained by a tribological chemical reaction and having a great difference in ionic potential therebetween are mixed with each other, the resulting binary composite oxide mixture shows low-melting-point properties, and thus a nano-sized tribo-film is formed on the thin film such that the thin film exhibits low friction properties. Low-melting-point double oxide systems known to have such properties include, in addition to MoO₃—CuO, various binary oxide systems. As described above, adding an element, which forms a low-melting-point binary oxide by a tribological chemical reaction, together with adding a substitutional element having low solubility to a base element which can form a nitride, can be a very efficient method of nanostructuring a thin film and diversifying the function of the thin film.

To add such a substitutional element, a second component target source is required, and to reproducibly control the chemical composition of a thin film, the independent and precise control of power for a dual target is required. In addition, because two kinds of elements have a serious difference in melting point therebetween and are not mutually miscible, they are difficult to prepare into a single alloy target having a uniform composition. If the macro or micro-segregation of components occurs by phase separation during solidification in the preparation of a single alloy target, a local difference in sputtering yield between the constituent phases having different atomic bonding energies will occur, and thus the distribution of concentration of the element along the thickness of the thin film will not be uniform, and the reproducibility and uniformity of the film structure cannot be guaranteed.

Accordingly, in order to realize a more advanced nanostructured metallic hard thin film in future, a coating system composed of two or more mutually immiscible elements excluding nitrogen is required. In addition, in order to provide new functions (e.g., low friction function) to a hard thin film, an additional element (Mo, V, Co, Ag, Cu, or Ni) which can form a low-friction oxide by a tribo-chemical reaction should be added to the thin film. This suggests that an advanced multi-component coating system which is more complex than current coating systems should be provided. Therefore, in order to reproducibly realize a multifunctional, multi-component nanostructured hard thin film, actually feasible approaches related to a parent material composition for the multi-component nanostructured hard thin film and a preparation method thereof are required.

### DISCLOSURE

### Technical Problem

Accordingly, the present invention has been made in order to solve the above-described problems, and an object of the present invention is to provide a sputtering target of a multi-component single body and a preparation method thereof, which can efficiently form a multi-component nanostructured thin film having various required properties by ensuring both the chemical uniformity of an immiscible alloy system composed of a nitride forming metal and a non-nitride forming metal and the reproducibility of the film structure and can realize a complex multi-component coating system by single target control.

Another object of the present invention is to provide a method for fabricating a multi-component alloy-based nanostructured thin film, in which a hard thin film which satisfies not only high-hardness properties, but also various required characteristics such as high elasticity and low friction, can be formed using said target.

### Technical Solution

In order to accomplish the above objects, the present invention provides a sputtering target of a multi-component single body, which comprises an amorphous or partially crystallized glass-forming alloy system composed of a nitride forming metal element, which is capable of reacting with nitrogen to form a nitride, and a non-nitride forming element which has no or low solid solubility in the nitride forming metal element and does not react with nitrogen or has low reactivity with nitrogen, wherein the nitrogen forming metal element comprises at least one element selected from Ti, Zr, Hf, V, Nb, Ta, Cr, Y, Mo, W, Al, and Si, and the non-nitride forming element comprises at least one element selected from Mg, Ca, Sc, Ni, Cu, Ag, In, Sn, La, Au, and Pb.

In the sputtering target of the present invention, the nitride forming metal element is preferably contained at an atomic ratio of 40-80 at %. More preferably, the nitride forming metal element is contained at an atomic ratio of 60-80 at %.

The sputtering target may comprise at least one low-melting-point oxide forming element selected from Mo, V, Co, Ag, Cu, Ni, Ti, and W, which is capable of forming a low-friction oxide by a tribo-chemical reaction.

Preferably, the nitride forming metal element and the non-nitride forming element may be selected such that they have an atomic radius difference of 14% or more therebetween or have different crystal structures, but are not limited thereto.

The present invention also provides a method for preparing a sputtering target of a multi-component single body, the method comprising forming an amorphous or partially crystallized glass-forming alloy system from a nitride forming metal element, which is capable of reacting with nitrogen to form a nitride, and a non-nitride forming element which has no or low solid solubility in the nitride forming metal element and does not react with nitrogen or has low reactivity with nitrogen, wherein the nitrogen forming metal element comprises at least one element selected from Ti, Zr, Hf, V, Nb, Ta, Cr, Y, Mo, W, Al, and Si, and the non-nitride forming element comprises at least one element selected from Mg, Ca, Sc, Ni, Cu, Ag, In, Sn, La, Au, and Pb.

In the method for preparing the sputtering target, the sputtering target may be prepared by atomizing the alloy comprising the nitride forming metal element and the non-nitride forming element, and heating, pressurizing and sintering the atomized powder in a supercooled liquid region, thereby forming a bulk alloy.

Alternatively, the sputtering target may also be prepared by a direct casting method in which the nitride forming metal element and the non-nitride forming metal element are melted and rapidly solidified, thereby forming a bulk alloy. Alternatively, the sputtering target may also be prepared by crystallizing the nitride forming metal element and the non-nitride forming metal element by rapid solidification at a relatively low cooling rate using a induction-cold crucible, and making the crystallized metal element into a cast structure having a fine crystal, thereby forming a bulk alloy.

In addition, the present invention provides a method for fabricating a multi-component alloy-based nanostructured thin film, the method comprising preparing a target of an amorphous or partially crystallized glass-forming alloy system from a nitride forming metal element, which reacts with nitrogen to form a nitride, and a non-nitride forming metal element which does not react with nitrogen, and subjecting the target to selective reactive sputtering in a mixed gas atmosphere comprising nitrogen and inert gas, thereby forming a thin film on a substrate, wherein the nitrogen forming metal element comprises at least one element selected from Ti, Zr, Hf, V, Nb, Ta, Cr, Y, Mo, W, Al, and Si, and the non-nitride forming element comprises at least one element selected from Mg, Ca, Sc, Ni, Cu, Ag, In, Sn, La, Au, and Pb.

In the method for fabricating the nanostructured thin film, the mixed gas for sputtering may further comprise at least one reactive gas selected from an oxygen/oxygen source gas and a carbon/carbon source gas.

In some cases, an amorphous buffer layer caused by non-reactive sputtering is preferably formed between the substrate and the thin film caused by reactive sputtering.

### Advantageous Effects

According to the present invention as described above, a sputtering target composed of a multi-component single body having various properties can be prepared using a nitride forming metal element and a non-nitride metal element, which are mutually immiscible. Thus, a stable and uniform nanostructured thin film can be fabricated by preventing the concentration of the target element in the thin film composition from being non-uniform due to a difference in sputtering yield between the components of the target in the reactive sputtering process and providing a uniform distribution of a nitrogen element for synthesizing and distributing a nano-crystalline phase in the thin film.

In addition, according to the present invention, a complex multi-component coating system can be realized by single target control, a multifunctional nanostructured thin film which satisfies not only hardness properties, but also various required properties, such as elasticity and tribological properties, can be prepared in an economical and highly effective manner.

### DESCRIPTION OF DRAWINGS

FIGS. 1 and 2 show the shape of powder of 100 μm or less and the microstructure of sintered powder, prepared from the parent material of a sputtering target according to the present invention.

FIGS. 3 and 4 show SEM and back-scattered electron (BSE) photographs of the target surface in an area obtained by ion-etching after sputtering of a composition of example 3.

FIGS. 5 to 10 show the results of X-ray diffraction analysis carried out to examine the crystalline structures of atomized powders, sintered sputtering targets, and thin films deposited by non-reactive sputtering and reactive sputtering processes, for compositions of examples 2, 3, 5, 12, 14 and 15.

FIGS. 11 and 12 show back-scattered electron (BSE) photographs of the top surface of reactive sputtering films having compositions of the examples of the present invention.

FIG. 13 shows an FE-SEM of the fracture surface of a coating film formed on a silicon substrate.

FIGS. 14 and 15 show low-magnification and high-magnification TEM photographs of a coating film.

FIGS. 16 and 17 are TEM SAD pattern photographs of an amorphous layer area and a lower layer area.

FIGS. 18 and 19 are graphs showing the hardness and elastic modulus of a reactive sputtering layer as a function of a composition of the example of the present invention.

FIGS. 20 to 22 are high-resolution TEM photographs of a non-reactive sputtering film and a reactive sputtering film layer as a function of the amount of DC plasma power.

FIGS. 23 to 26 show the results of analyzing the TEM SAD pattern of a coating layer surface on a TEM photograph.

FIGS. 27 and 28 show the results of XRD analysis and nanoindentation measurement of a composition of example 3 as a function of deposition conditions.

FIG. 29 shows an FE-SEM photograph of a film deposited for 4 hours.

FIG. 30 shows the results of measuring the depth profile of target elements including nitrogen in a region from the top surface of a film to a substrate portion using GDOES (glow discharge optical emission spectroscopy).

### BEST MODE

The above objects, features and advantages of the present invention will be more apparent from the following embodiments explained with respect to the accompanying drawings.

In embodiments of the present invention disclosed in the text of the present invention, specific structural or functional descriptions are exemplified to merely describe the embodiments of the present invention, and the embodiments of the present invention can be implemented in various forms and should not be interpreted as being limited to the embodiments described in the text of the present invention.

The present invention can be variously modified and can have various forms, and specific embodiments are intended to be shown in the drawings and to be described in detail in the specification. However, this is not intended to limit the present invention to specific embodiments, and it should be understood that the present invention includes all modifications, equivalents or replacements included in the spirit and scope of the present invention.

Terms, such as “first” and/or “second,” can be used to describe various components, but the components are not limited by the terms. The terms are merely used to distinguish one component from another component. For example, the first component can be designated as the second component without departing from the scope of the present invention, and, similarly, the second component can also be designated as the first component.

When it is stated that a specific component is “connected” or “coupled” to another component, it should be understood that the specific component, can be directly connected or linked, but other components may be interposed between the specific component and the other component. In contrast, when it is stated that a specific component is “directly connected” or “directly coupled” to another component, it should be understood that no other components are interposed between the specific component and the other component. Other expressions for describing the relationship between components, that is, “between ˜”, and “immediately between ˜”, or “adjacent to ˜”, and “immediately adjacent to ˜”, should be interpreted in the same manner.

The terms used in the present specification are used only to describe specific embodiments, and are not intended to limit the present invention. Singular expressions may include the meaning of plural expressions unless otherwise clearly specified. In the present application, it should be understood that terms such as “comprises” or “has”, are intended to indicate that proposed features, numbers, steps, operations, components, parts, or combinations thereof exist, and the probability of existence or addition of one or more other features, steps, operations, components, parts or combinations thereof is not excluded thereby.

Unless otherwise defined, all terms used herein, including technical or scientific terms, are not defined otherwise, have the same meaning as terms generally understood by those skilled in the art. The terms, such as those defined in generally used dictionaries, should be interpreted as having the same meaning as the terms in the context of related arts, and are not to be interpreted to have meanings that are ideal or are excessively formal, when the terms are not explicitly defined in the present specification.

Hereinafter, preferred embodiments of the present invention will be described in detail with reference to the accompanying drawings. Like reference numbers in each of the drawings indicate like members.

The sputtering target of the present invention is an amorphous or partially crystallized multi-component single-alloyed target comprising a nitride forming metal (active metal) and a non-nitride forming metal (soft metal). For example, it may be used in the fabrication of multifunctional nanostructured thin films, including protective hard coatings having not only high hardness properties, but also low-friction properties, which are formed by sputtering on the surface of driving parts or tool parts.

In the present invention, the multi-component sputtering target alloy target composition may be based on a bulk amorphous alloy system having a glass-forming ability (GFA) of 1 mm or more. The bulk amorphous alloy scientifically refers to an alloy which can be cast to a thickness of 1 mm or more.

The sputtering target can be prepared by preparing an amorphous alloy powder from a multi-component alloy parent material using the glass-forming ability of the bulk amorphous alloy by a rapid solidification method such as gas atomization, and densifying the amorphous alloy powder using the viscous flow properties of the bulk amorphous alloy in a supercooled liquid temperature region.

When the above sputtering target is used, an active metal among the mutually immiscible active metal and soft metal contained in the target reacts with nitrogen to form a hard nitrogen compound (nitride) in a process of forming a film by sputtering in a mixed gas atmosphere of argon and nitrogen under reduced pressure, and the soft metal itself participates in film formation, thereby forming a multi-component multifunctional nanostructured thin film composed of two or more phases including a nitride phase and a soft metal phase.

The sputtering target of the present invention as described above can form a uniform nanostructured thin film without a difference in sputtering yield between the elements by eliminating the segregation of the elements and maximizing the chemical homogeneity of the elements. In addition, the present invention can diversify the chemical complexity of a target material, and thus can provide a method of realizing a high-density nanostructured thin film having high structural complexity and dense atomic packing. Moreover, the present invention can provide a nano-composite coating film, which is composed of a mixture of an active metal nitride (AMeN) and a soft metal (SMe) and has low friction and high hardness properties, using a single target through a selective reactive sputtering process. Furthermore, the present invention can provide a novel coating method which can be applied in future to a systematic design of low-friction/high-hardness thin films and the development of film formation technology.

### MODE FOR INVENTION

Table 1 below shows the properties of sputtering and reactive sputtering thin films formed from glass-forming alloy compositions as the parent materials of sputtering targets according to the present invention and indicates examples 1 to 16 for the sputtering targets of the present invention and comparative examples 1 to 3. In the following description, the examples designate those shown in Table 1.

TABLE 1

| | Target material | | | | | | | | |
|---|---|---|---|---|---|---|---|---|---|
| | | Ratio | | | | | | | |
| | | (%) of | Constituent | Sputtering film | | | Reactive sputtering film | | |
| Examples/ | | nitride | phases of | | Elastic | Constituent | | Elastic | Constituent |
| Comparative | Chemical composition | forming | sintered | Hardness | modulus | phases of | Hardness | modulus | phases of |
| Examples | (at %) | element | material | (GPa) | (GPa) | film | (GPa) | (GPa) | film |
| Example 1 | Zr₅₅Al₂₀Ti₅Ni₁₀Cu₁₀ | 80.0 | Crystalline + | 6.5 | 110.7 | Amorphous | 26.0 | 256.3 | nc-ZrN + |
| | | | amorphous | | | | | | amorphous |
| Example 2 | Zr_{62.5}Al₁₀Fe₅Cu_{22.5} | 77.5 | Amorphous | 6.7 | 113.8 | Amorphous | 23.1 | 251.5 | nc-ZrN + |
| | | | | | | | | | amorphous |
| Example 3 | Zr_{62.5}Al₁₀Mo₅Cu_{22.5} | 77.5 | Amorphous | 7.0 | 119.0 | Amorphous | 22.6 | 237.5 | nc-ZrN + |
| | | | | | | | | | amorphous |
| Example 4 | Zr_{58.5}Al₉Mo₁₀Ni₉Cu_{13.5} | 77.5 | Crystalline + | 6.2 | 114.5 | Amorphous | 25.9 | 261.7 | nc-ZrN + |
| | | | amorphous | | | | | | amorphous |
| Example 5 | Zr₆₃Al_{7.5}Mo₄V₂Ni₆Cu_{12.5}Ag₅ | 76.5 | Crystalline + | 6.0 | 102.1 | Amorphous | 26.8 | 260.3 | nc-ZrN + |
| | | | amorphous | | | | | | amorphous |
| Example 6 | Zr_{61.8}Al_{9.5}Cr₅Ni_{9.5}Cu_{14.2} | 76.3 | Crystalline + | 6.3 | 107.1 | Amorphous | 25.6 | 247.8 | nc-ZrN + |
| | | | amorphous | | | | | | amorphous |
| Example 7 | Zr₅₅Al₂₀Ni₂₅ | 75.0 | Crystalline + | 6.0 | 109.2 | Amorphous | 25.7 | 251.6 | nc-ZrN + |
| | | | amorphous | | | | | | amorphous |
| Example 8 | Zr₆₅Al₁₀Co₁₀Cu₁₅ | 75.0 | Crystalline + | 6.1 | 110.7 | Amorphous | 25.1 | 253.5 | nc-ZrN + |
| | | | amorphous | | | | | | amorphous |
| Example 9 | Zr₆₁Al_{7.5}Ti₂Nb₂Ni₁₀Cu_{12.5}Ag₅ | 72.5 | Amorphous | 6.1 | 114.7 | Amorphous | 25.3 | 268.5 | nc-ZrN + |
| | | | | | | | | | amorphous |
| Example 10 | Zr₆₅Al_{7.5}Ni₁₀Cu_{17.5} | 72.5 | Amorphous | 6.4 | 120.9 | Amorphous | 29.3 | 256.9 | nc-ZrN + |
| | | | | | | | | | amorphous |
| Example 11 | Zr₅₇Al₁₀Nb₅Ni_{12.6}Cu_{15.4} | 72.0 | Amorphous | 6.5 | 118.7 | Amorphous | 22.3 | 230.1 | nc-ZrN + |
| | | | | | | | | | amorphous |
| Example 12 | Zr₅₅Al₁₀Ni₅Cu₃₀ | 65.0 | Amorphous | 7.2 | 124.5 | Amorphous | 23.1 | 243.3 | nc-ZrN + |
| | | | | | | | | | amorphous |
| Example 13 | Zr_{50.7}Al_{12.3}Ni₉Cu₂₈ | 63.0 | Amorphous | 7.3 | 128.7 | Amorphous | 20.7 | 222.0 | nc-ZrN + |
| | | | | | | | | | amorphous |
| Example 14 | Zr₅₀Ti₁₆Ni₁₉Cu₁₅ | 66.0 | Crystalline + | 6.7 | 121.4 | Amorphous | 23.6 | 231.5 | nc-ZrN + |
| | | | amorphous | | | | | | amorphous |
| Example 15 | Ti₄₅Zr₅Ni₅Cu₄₅ | 50.0 | Crystalline + | 7.4 | 133.7 | Amorphous | 19.8 | 198.7 | nc-ZrN + |
| | | | amorphous | | | | | | amorphous |
| Example 16 | Ti₃₄Zr₁₁Ni₈Cu₄₇ | 45.0 | Crystalline + | 7.5 | 132.1 | Amorphous | 15.7 | 164.2 | nc-TiN + |
| | | | amorphous | | | | | | amorphous |
| Comparative | Zr₂₂Ti₁₈Ni₆Cu5₄ | 40.0 | Crystalline + | 7.9 | 137 | Amorphous | 11.8 | 191.1 | nc-TiN + |
| Example 1 | | | amorphous | | | | | | amorphous |
| Comparative | Ti | 100 | Crystalline + | — | — | — | 26.7 | 435.3 | nc-TiN |
| Example 2 | | | amorphous | | | | | | crystalline |
| Comparative | Zr | 100 | Crystalline + | — | — | — | 25.0 | 328.1 | nc-TiN |
| Example 1 3 | | | amorphous | | | | | | crystalline |

[Test]

Alloys used as the parent target materials in the examples of the present invention were alloys which contained a nitride forming element, such as Zr, Al, Ti, Nb, Cr, Mo or Fe, at a ratio of 40-80 atomic %, and had a composition having a glass-forming ability of 1 mm or more. These alloys were composed of a nitride forming element (active metal) and a non-nitride forming element (soft metal).

The multi-component raw material mixtures having the above composition ratios were melted in a vacuum arc melting apparatus to form alloy ingots. The alloy ingots were melted again in a high-frequency heating apparatus by argon gas atomization, and then atomized with the same gas in an inert argon gas atmosphere to make amorphous powders.

The prepared amorphous powders were screened into powders of 100 μm or less through a 150-mesh screening device. Such powders of 100 μm or less were placed in a graphite mold (having an inner diameter of 3 inches) in an amount corresponding to a sintered material thickness of 6 mm in view of the theoretical specific gravity of each alloy composition. Then, the powders were densified by pressure using a pulse electric current sintering device in the supercooled liquid temperature region of each alloy composition, thereby preparing disk-shaped bulk sputtering targets having a diameter of 76.2 mm and a thickness of 6 mm. The sintering pressure applied to the powders and the mold during the pulse electric current sintering was set at 40-70 MPa.

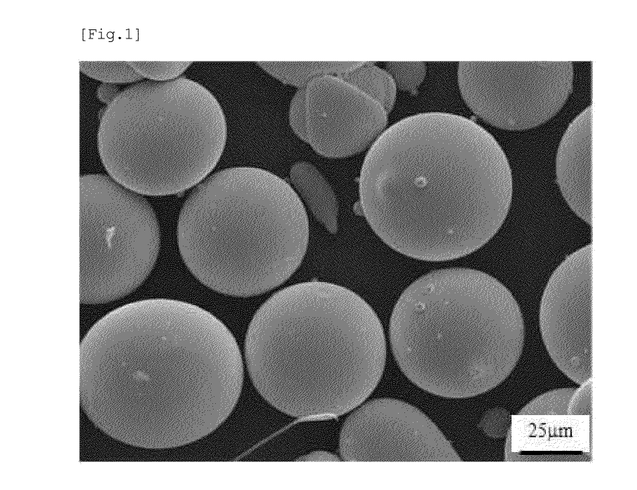

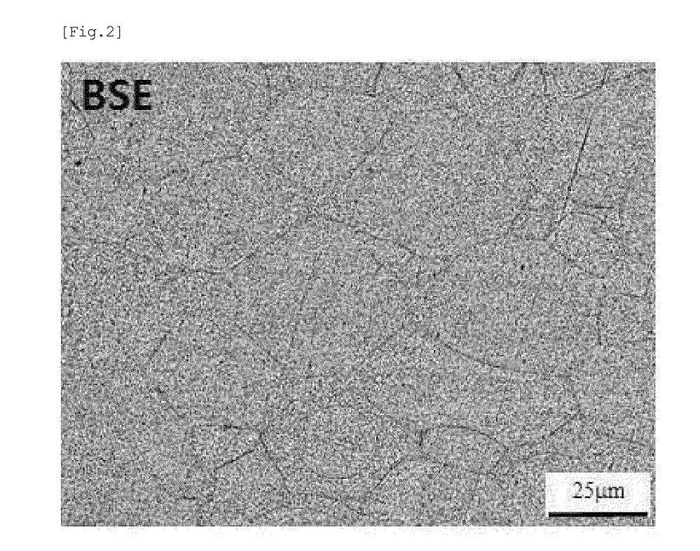

FIGS. 1 and 2 show the shape of the prepared powder having a size of 100 μm or less and the microstructure of sintered powder. The sintered powder has a dense microstructure having a relative density of 99% or more as a result of deformation of spherical amorphous powder, and has no powder particle boundary. In addition, the sintered powder shows a typical amorphous structure obtained by densifying amorphous powder by plastic deformation in a supercooled liquid temperature region.

The results of analysis with a Cu Kα X-ray diffraction analyzer indicated that the powders of 100 μm or less were all amorphous. This is because the alloys used in the test had a high glass-forming ability of 1 mm or more. Some of the sintered powders were amorphous, but some of the alloy compositions were partially crystallized during the sintering of the powder. This partial crystallization can occur when the sintering temperature cycle in the powder sintering process exceeds the supercooled liquid temperature region of the amorphous alloy or the maintenance time in this temperature region is not kept. This pulse electric current sintering process has been frequently used as a method for sintering amorphous alloys requiring a short-time heating cycle, because the control of a short-time heating/cooling cycle is easier than that in a traditional hot-press furnace.

However, the temperature of conductive powder such as an amorphous metal in a mold, which reaches by powder electric current resistance by electric current resistance heating of the powder, reaches the highest at the center of the powder in the mold and decreases in the diameter direction of the powder, because the electric current has a tendency to be concentrated on the center of the powder. Actually, a temperature sensor (K-type thermocouple in this invention) which is used to control sintering temperature during electric current sintering is difficult to come in direct contact with powder and is located in the center of the outer wall of a mold, which has low temperature, and thus the temperature of the powder can be indirectly predicted by measuring only the temperature of the mold. Thus, this partial crystallization can be caused by difficulty in controlling accurate sintering temperature and time. If necessary, the method can be improved into an accurate and efficient method of measuring temperature depending on the supercooled liquid temperature region of each alloy, and the temperature cycle can be optimized, thereby making it possible to prepare a bulk sintered powder while maintaining the amorphous structure of the powder.

This amorphous or partially crystallized sintered glass-forming alloy powder was used as the parent material of a sputtering target, and thin films were obtained by normal non-reactive sputtering and reactive sputtering processes using DC magnetron plasma power. The non-reactive sputtering process was performed under the following deposition conditions: the distance between the target and the substrate surface: 70 mm; the chamber pressure: 5 mTorr; and the flow rate of argon gas: 36 sccm. The reactive sputtering process was performed under the following deposition conditions: the distance between the target and the substrate surface: 50 mm; the chamber pressure: 5 mTorr; the flow rate of argon gas: 30 sccm; the flow rate of reactive nitrogen gas: 6 sccm; and the ratio of the flow rate of argon gas to that of nitrogen gas: 5:1. The DC power was set at 300 W, and the substrate was not heated by a separate heating device. For evaluation of the obtained thin films, the hardness and elastic modulus of the thin films were measured by a nanoindentation method, and the structure and crystalline properties of the thin films were analyzed by an X-ray diffraction analyzer, FE-SEM, and HR-TEM.

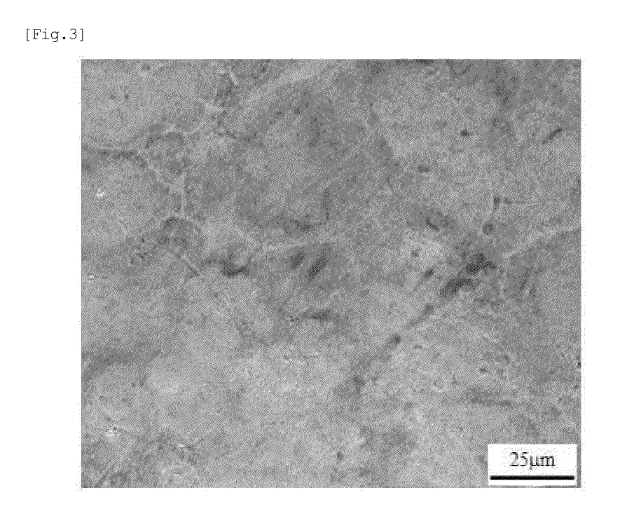

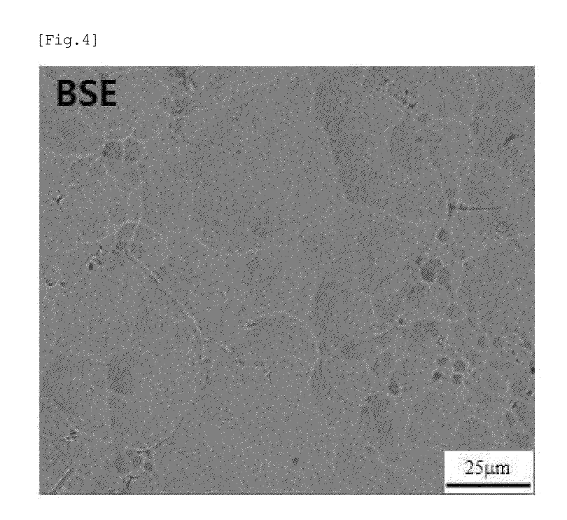

FIGS. 3 and 4 show SEM and back-scattered electron (BSE) photographs of the target surface in an area obtained by ion-etching after sputtering of a composition of example 3. The secondary electron image showed that the target surface was very smooth, suggesting that sputtering occurred uniformly. Meanwhile, in the back-scattered electron photograph of the same area, the internal grain boundary is shown to be exposed, suggesting that the sintered body has the same structure as the structure of the sintered body shown in FIGS. 1 and 2. Thus, in the case of this sintered body, new phases other than the amorphous phase did not appear during the sputtering process, and there was no difference in sputtering depth in the grain boundaries and the grains, suggesting that uniform sputtering occurred throughout the target surface.

[Non-Reactive Sputtering Test]

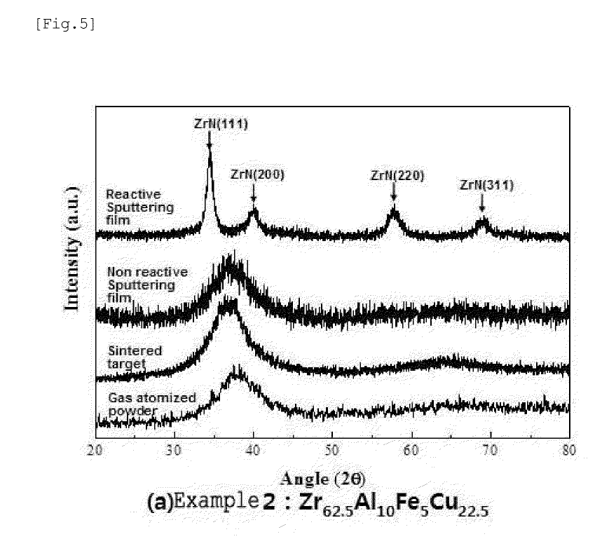

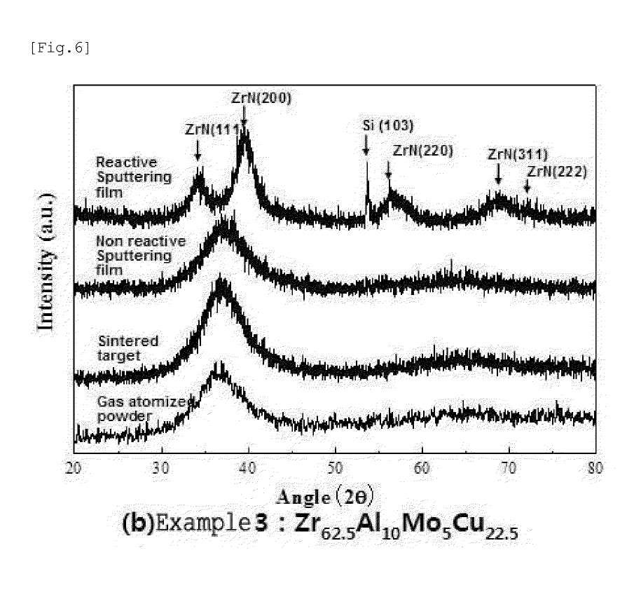

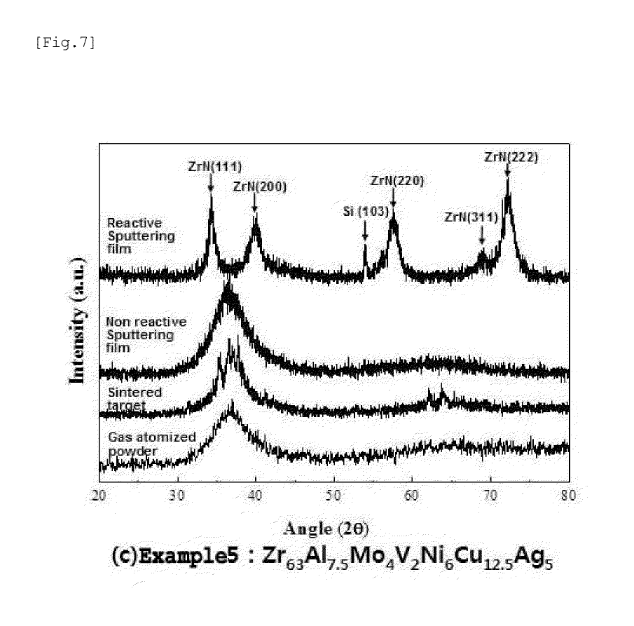

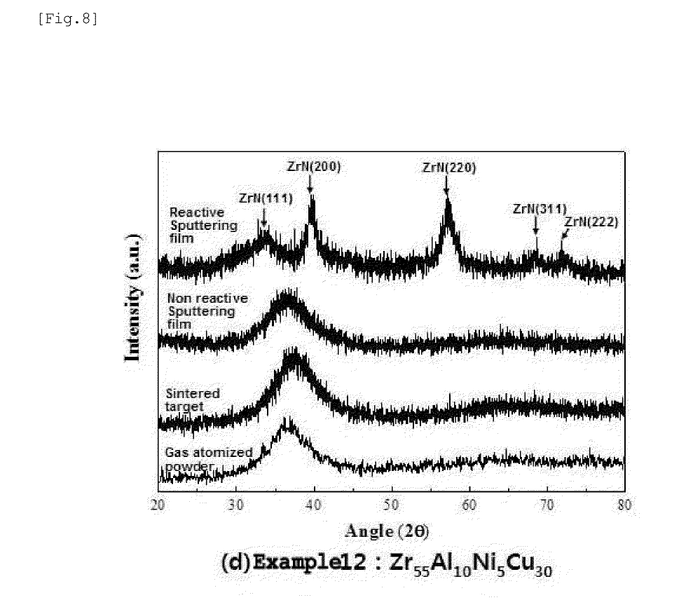

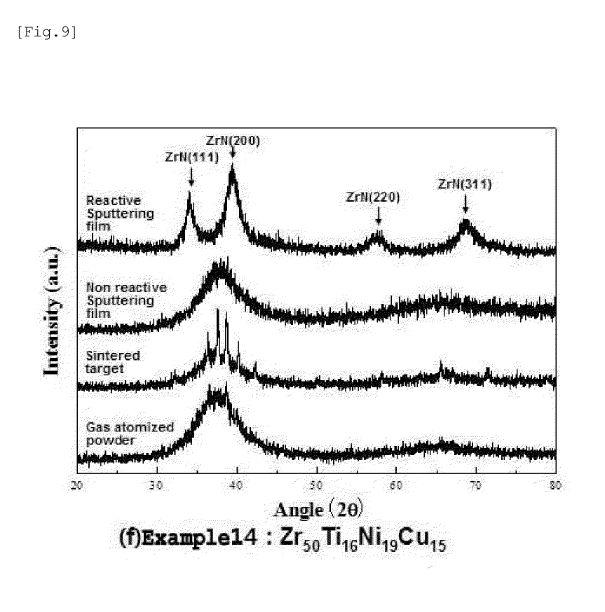

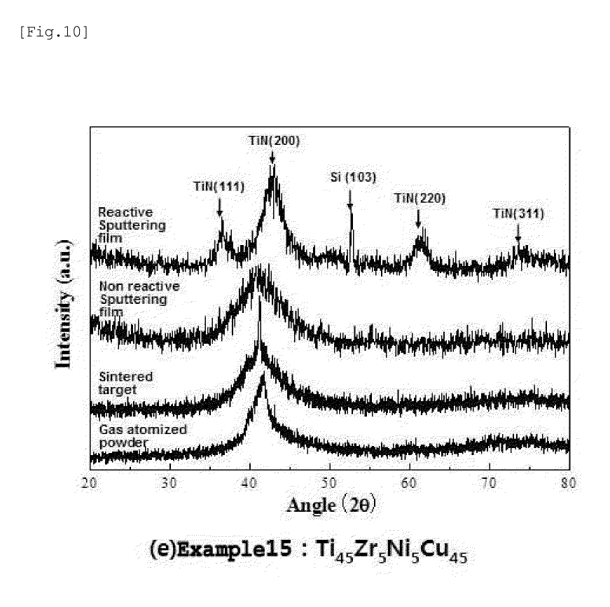

FIGS. 5 to 10 show the results of X-ray diffraction analysis carried out to examine the crystalline properties of atomized powders, sintered sputtering targets, and thin films deposited by non-reactive sputtering and reactive sputtering processes, for compositions of examples 2, 3, 5, 12, 14 and 15. Table 2 below the diffraction Bragg angles of reactive sputtering thin films resulting from the compositions of the examples.

TABLE 2

| | | | Results of XRD analysis | | | | | |
|---|---|---|---|---|---|---|---|---|
| | | | Composition | Composition | Composition | Composition | Composition | Composition |
| Plane | Reference | | of Example 2 | of Example 3 | of Example 5 | of Example 12 | of Example 14 | of Example 15 |
| index | ZrN | TiN | ZrN | ZrN | ZrN | ZrN | ZrN | TiN |
| 111 | 33.918 | 36.730 | 34.29 | 34.09 | 34.53 | 33.97 | 34.16 | 36.66 |
| 200 | 39.362 | 42.669 | 39.85 | 39.61 | 39.93 | 39.73 | 39.44 | 42.94 |
| 220 | 56.885 | 61.929 | 57.53 | 56.33 | 57.45 | 57.33 | 57.16 | 61.56 |
| 311 | 67.914 | 74.215 | 68.77 | 68.63 | 68.97 | 68.17 | 67.92 | 74.06 |
| 222 | 71.380 | 78.121 | — | 72.01 | 71.95 | 71.97 | — | — |

* Reference
Wavelength: Cu-Ka(ave.) 1.54184
ZrN: Natl. Bur. Stand. (U.S.) Monogr. 25, 21, 136 (1984)
TiN: Calculated from ICSD using POWD-12++, (1997)
Schoenberg. N., Acta Chem. Scand., 8, 213 (1954)

The amorphous alloy powders were all amorphous. It was shown that the non-reactive sputtering thin films obtained using inert argon gas alone were also amorphous. In addition, the position of (2θ value) of the diffuse Bragg peak was similar to the position of the corresponding amorphous powder that is the parent material. In other words, the position of the Bragg peak of the amorphous powder varies slightly depending on the composition of the alloy, and the position of the Bragg peak of the amorphous sputtering thin film corresponding to the alloy material is the same as that of the corresponding parent material powder. This suggests that the composition and structure of the parent material amorphous alloy were congruently transferred into the thin film through the non-reactive sputtering process.

The results of a study conducted by A. L. Thomann indicated that a thin film deposited by RF magnetron non-reactive sputtering using the parent material of a glass-forming alloy target of crystallized Zr₅₂Ti₆Al₁₁Cu₂₁Ni₁₃ had a composition similar to that of the parent material and that the thin film could be formed to have an amorphous structure due to the intrinsic nature (i.e., glass-forming ability) of the alloy. The results of this example can appear to be similar to the results of the previous study. However, it is difficult to consider that the reason why the amorphous thin film is formed is necessary because the glass-forming ability of the parent target material is high. It is generally known that a very high cooling rate of 10° C./sec or higher can be achieved during the synthesis of thin films by sputtering. In addition, an amorphous alloy having a glass-forming ability of 1 mm or more sufficiently forms a non-equilibrium amorphous phase at a cooling rate of 10° C./sec or higher. Therefore, it is believed that, when an alloy which has glass-forming ability (i.e., a tendency to become a non-equilibrium phase rather than an equilibrium phase) in a sputtering deposition process under the condition of high cooling rate significantly higher than the critical cooling rate of a glass-forming alloy is used as a parent target material, it can be more easily formed into an amorphous thin film by synergistic effects. This suggests that, in the process of synthesizing an amorphous thin film by sputtering using an alloy having glass-forming ability as a parent target material, the structure and constituent phase of the target do not necessarily need to be amorphous.

[Reactive Sputtering Test]

In the results of the X-ray diffraction analysis (Cu Kα) of the reactive sputtering thin films obtained by a mixed gas of argon and nitrogen as shown in FIGS. 5 to 10, the reactive sputtering films have resolvable crystalline peaks, unlike the non-reactive sputtering films and the amorphous powders, and thus show clear crystalline properties. The results of analyzing the 20 position of the crystalline peaks suggest that the four compositions all have the same ZrN or TiN crystal, and the application of the measured main peaks to the Scherrer equation indicates that these crystals are nanocrystals having a size of less than 30 nm. Thus, the reactive sputtering films show nano-crystalline structures, unlike the non-reactive sputtering films. Such XRD results show that the cause of the crystallization has no connection with a general amorphous crystallization behavior caused by the production of an intermetallic compound by a reaction between the components of the parent target material. In other words, it can be concluded that the crystallization is caused only by the nitrification of the nitride-forming element (such as zirconium (Zr) or titanium (Ti) which is the main element of the parent material alloy) with a nitrogen element which is a reactive gas element. In addition, it is very important that nano-sized crystals are present in the thin films, unlike prior traditional ZrN.

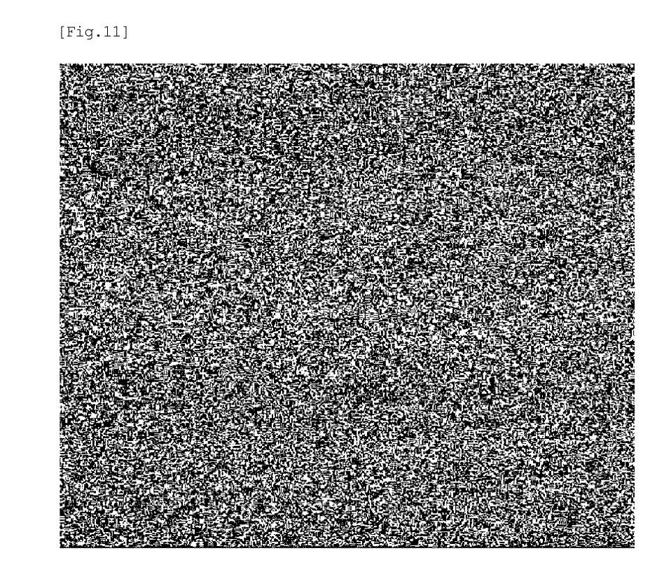

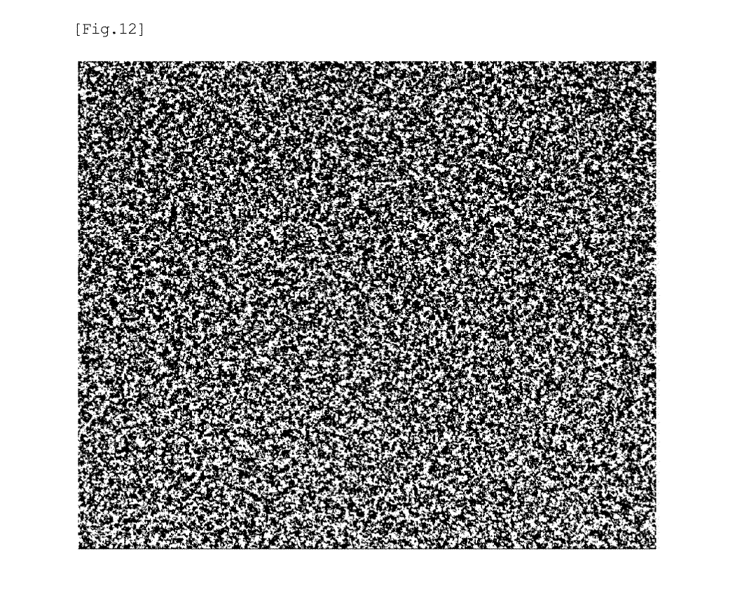

FIGS. 11 and 12 show back-scattered electron photographs showing the results of observing the surface of the sputtering thin film, having the composition of the example, with FE-SEM. As can be seen therein, micro-segregation was not observed on the surface of the formed nitride thin film, and the coating layer was formed uniformly throughout the surface.

[SEM Observation and Transmission Electron Microscopy of Fracture Surface of Coating]

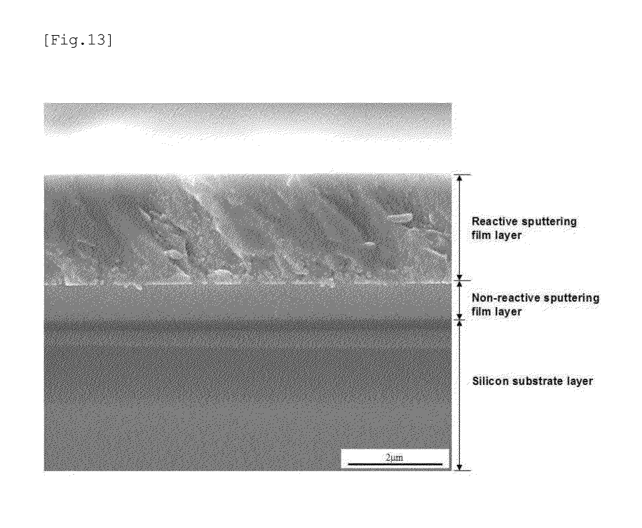

FIG. 13 shows an FE-SEM photograph of the fracture surface of a coating formed on a silicon substrate. In the formation of films, an amorphous thin film was formed on a substrate by a non-reactive sputtering process (distance between target and substrate: 7 cm; power: 250 W; and deposition time: 10 min), and then a nitride film layer was formed thereon using nitrogen gas by a reactive sputtering process (distance between target and substrate: 5 cm; power: 300 W; and deposition time: 20 min). The amorphous alloy composition used herein was a composition of example 5 (Zr₆₃Al_{7.5}Mo₅V₂Ni₆Cu_{12.5}Ag₅). When the interfaces between the amorphous film layer as the intermediate layer deposited by non-reactive sputtering and the overlying nitride layer and between the intermediate layer and the underlying silicon substrate are carefully observed, it can be seen that smooth and continuous interfaces are formed without cracks or voids.

Meanwhile, the fracture patterns of the reactive sputtering layer and the non-reactive sputtering layer significantly differ from each other. In other words, the amorphous film layer shows a vein-like fracture pattern or striation-like fracture pattern caused by the propagation of a shear band, which is the characteristic fracture mode of the bulk amorphous parent material, whereas the reactive sputtering layer shows a brittle fracture pattern with high hardness. Thus, it can be seen that the structures or mechanical properties of the two layers significantly differ from each other.

For high-resolution transmission electron microscopy, a deposited sample was prepared. In deposition conditions, the non-reactive deposition and reactive deposition times were reduced to ½ such that the total thickness of the hybrid film layer was reduced to half of the sample used in the SEM analysis for observation of the fracture surface, and other deposition conditions were the same as those in the SEM analysis. The sample was subjected to mechanical polishing and ion milling processes, thereby preparing a sample for TEM analysis.

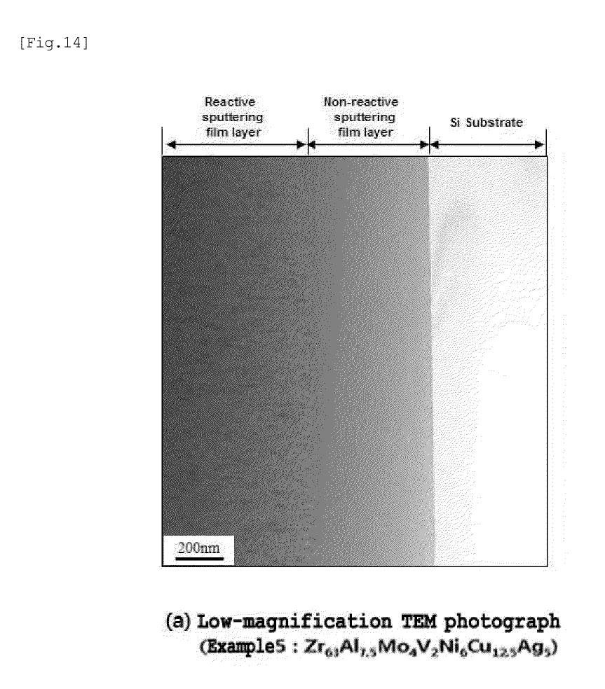

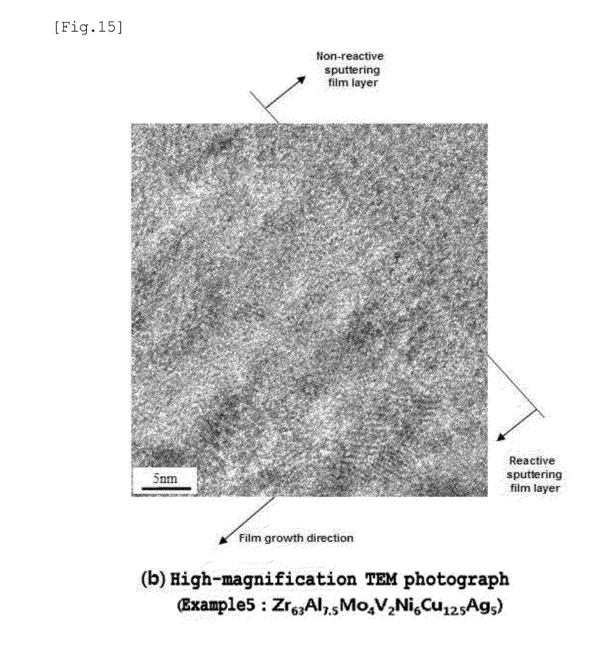

FIGS. 14 and 15 show low-magnification and high-magnification TEM photographs of the coating layers. In the low-magnification photograph, each interface is continuous and smooth without any crack or void as observed in the SEM photograph of the fracture surface. Herein, it can be seen from the difference in contrast that the amorphous layer is generally uniform without showing the difference in contrast, whereas the reactive sputtering layer include spot-like phases formed in the growth direction of the thin film. Such phases having dark contrast appear to form lattice patterns as shown in the high-magnification photograph, and thus these phases appear to be nano-crystals having a size of 5-20 nm.

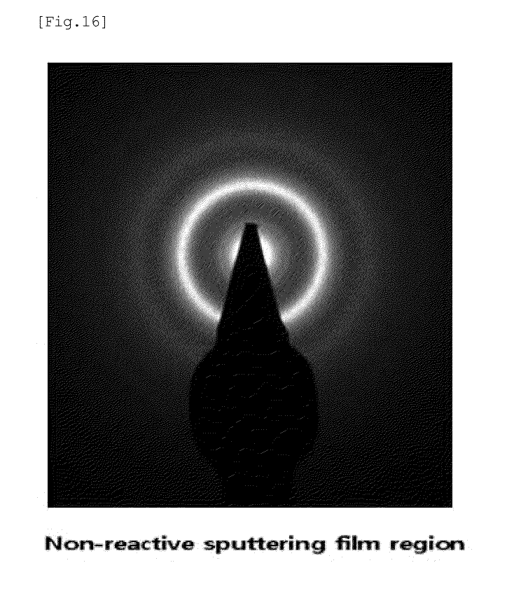

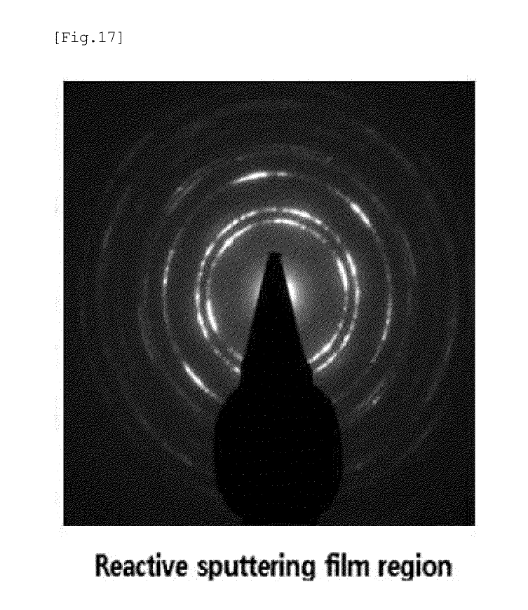

The results of analyzing the electron diffraction pattern of the selective area of each of the non-reactive and reactive sputtering film layers clearly indicate the crystalline structures of the two areas (see FIGS. 16 and 17). In other words, the non-reactive sputtering area shows a diffuse or broad halo electron diffraction pattern, and the reactive sputtering area shows faint points which indicate nano-sized crystalline structures. In the high-magnification TEM photograph, random atomic arrange patterns resulting from amorphous structures can be observed in the non-reactive sputtering layer, and this atomic arrangement appears to be continuously expanded to some areas of the reactive sputtering layer. This is a result which could not be seen through the macroscopic observation of the SEM photograph of the fracture surface or the low-magnification TEM photograph. In addition, the nano-crystals in the sputtering layer are surrounded by the amorphous base and isolated from each other, and these crystals show a fully percolated structure.

Thus, through the X-ray diffraction analysis of the non-reactive and reactive sputtering films, together with the FE-SEM observation and TEM analysis of the hybrid coating composed of these films, it was demonstrated that, when the parent material of the multi-component glass-forming alloy target is used, the structure of produced thin films can be controlled from an amorphous metal material to an amorphous phase-based composite material containing a nano-nitride phase, depending on the introduction of reactive nitrogen gas in the sputtering process, thereby achieving the hybridization of two thin films having different physical properties.

Particularly, as shown in the examples of Table 1, the amorphous thin films deposited by the non-reactive sputtering process show a low hardness of 10 GPa or less, whereas the reactive sputtering thin films formed by introducing reactive nitrogen gas show a high hardness of 15-27 GPa as a result of an increase in the fraction of the nitride forming element and the resulting decrease in the fraction of the soft metal. This hardness value approaches the hardness value of TiN and ZrN formed using a pure element target as shown in the comparative examples. This can be believed to be because the nitride forming element in the parent material reacts with a nitrogen gas element to form nano-crystalline phases in the amorphous base and form nanostructures, thereby achieving the Hall Petch effect according to grain refinement.

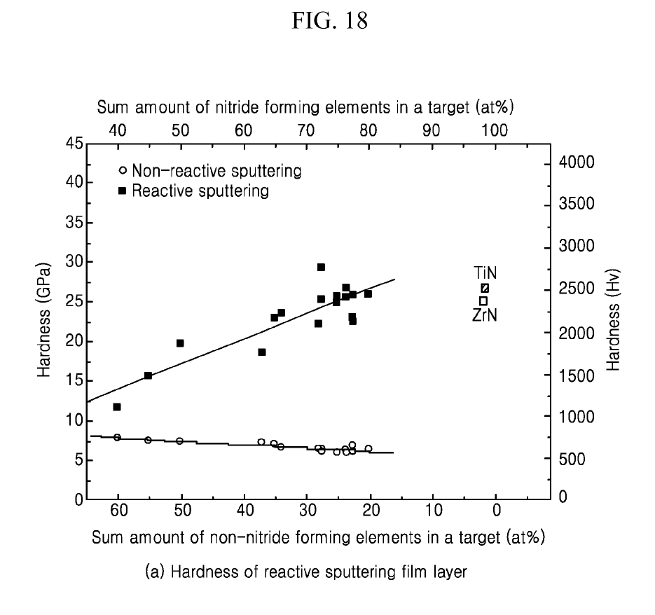

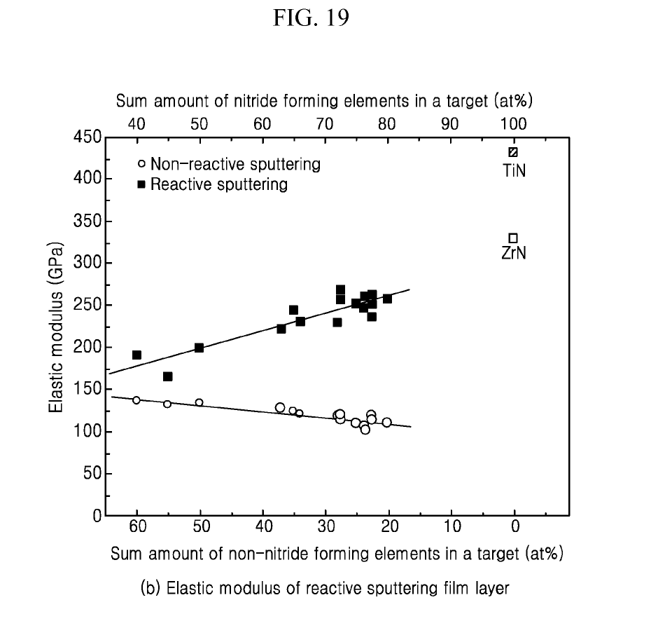

Meanwhile, the reactive sputtering thin films a high elastic modulus of 200 GPa or more due to the increase in hardness and the incorporation of a nano-sized nitrogen compound, but show a low elastic modulus (164-268 GPa) compared to TiN (435 GPa) and ZrN (328 GPa) as shown in the comparative examples (see FIGS. 18 and 19). In comparison with the case of the comparative examples in which a pure element target such as Ti or Zr is used, the multi-component parent target material in which the non-nitride forming soft metal element immiscible in the nitride forming element is contained in the target in an amount of 20-60% is used, whereby a nanocomposite of an amorphous metal phase having a low elastic modulus and a hard ceramic nitride film is formed which shows a high H/E index (0.1).

[Effect of Amount of DC Power on Properties of Reactive Sputtering Film]

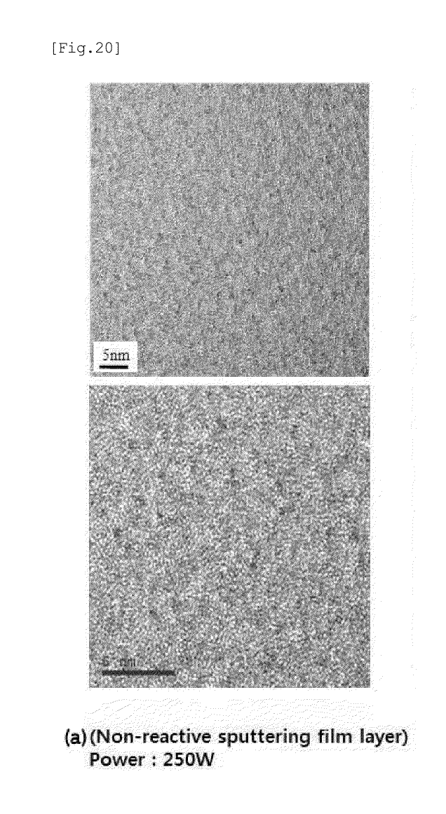

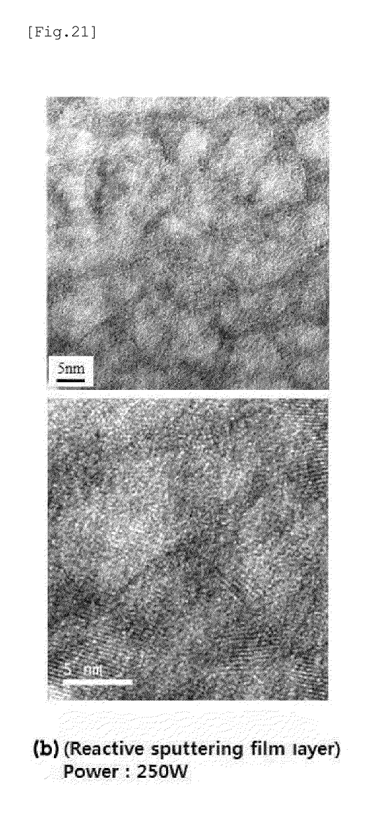

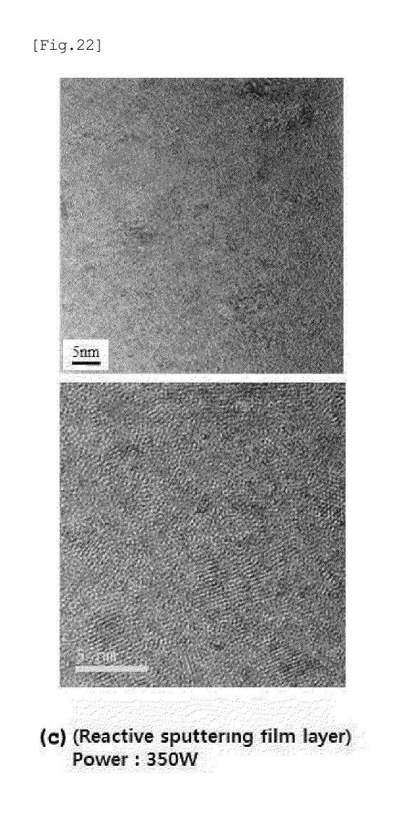

FIGS. 20 to 22 are high-resolution TEM photographs of a non-reactive sputtering film and a reactive sputtering film obtained using various amounts of DC plasma power. The non-reactive sputtering film was deposited under the following conditions: the distance between the target surface and the substrate: 70 mm; powder: 250 W. The reactive sputtering film was deposited under the following conditions: the distance between the target surface and the substrate surface: 50 mm; the mixing ratio of argon and nitrogen: 5:1; and power: 250 W and 350 W. The composition used was an alloy having the composition of example 3 (Zr_{62.5}Al₁₀Mo₅Cu_{22.5}) shown in Table 1.

The non-reactive sputtering film shows an amorphous structure having random atomic arrangement, whereas the reactive sputtering film shows an area having regular atomic arrangement. In addition, with respect to the size and dispersed state of the nano-crystalline areas having regular atomic arrangement, it can be seen that, when the DC power is increased to 350 W, the crystalline phases become finer and the ratio of the crystalline phases increases. In other words, at a power of 250 W, the amorphous area and the crystalline area are clearly distinguished from each other and also have similar sizes. However, at a power of 350 W, the size of the amorphous area rapidly decreases compared to the case of 250 W, and the crystalline area forms the majority of the film.

Such results indicate that, as power increases, the deposition temperature increases, thereby promoting the nitriding reaction. It is noteworthy that, although an environment in which crystallization is promoted as a result of the increase in power is accelerated, the growth of crystals no longer progresses and small crystals appear. This can be macroscopically associated with the phenomenon in which the fraction of amorphous areas decreases, resulting in an increase in the fraction of crystalline areas.

However, it is believed that this increase in the fraction of crystalline areas does not result from the middle-range and long-range diffusion of the elements, but rather the fraction of amorphous areas is decreased by the short-range diffusion of less than 5 nm, resulting in an increase in the fraction of crystalline areas. It appears that this phenomenon in which Zr and N atoms playing a main role in the crystallization of amorphous areas are difficult to move by long-range diffusion is attributable to the unique characteristics of atomic arrangement of the amorphous base phase that is an interphase located between nano-crystals. In other words, this phenomenon is because multi-component atoms having a atomic radius difference of 14% or more are randomly packed at a very high packing efficiency (density). Moreover, in the sputtering process having a high cooling rate of about 10° C./sec, a nitrogen atom which is a reactive gaseous element and has the smallest size among the constituent elements of the thin film is easily supersaturated and condensed in the amorphous base phase having high atomic packing efficiency, and the amorphous base phase having the nitrogen element added thereto has a smaller free volume. This results in an increase in the atomic packing efficiency, and the middle-range and long-range diffusion of the nitrogen atom for the nitrification reaction becomes more difficulty.

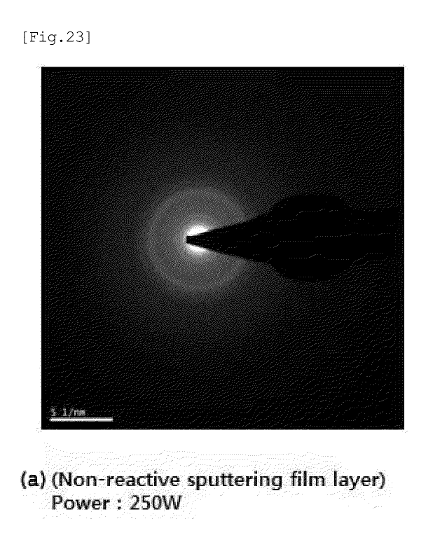

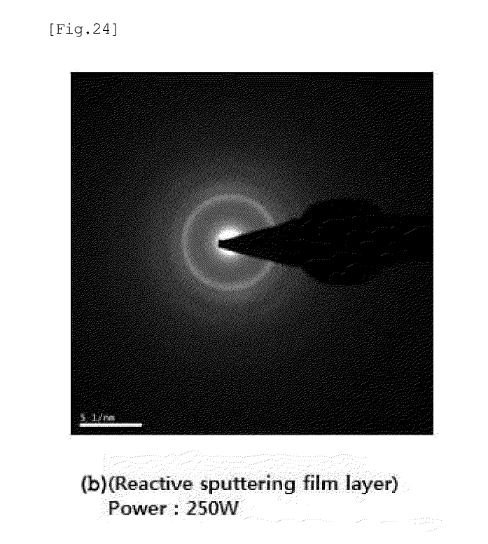

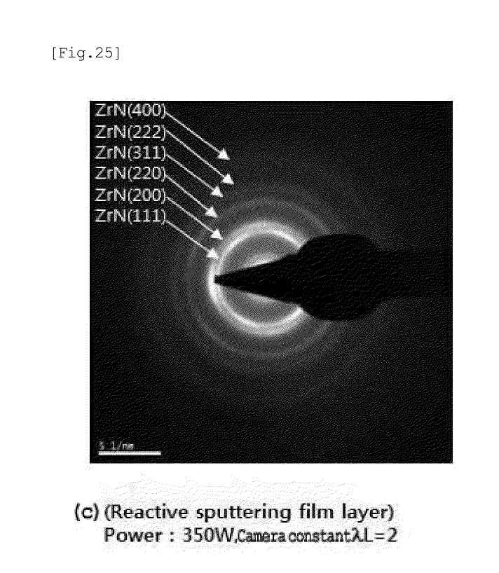

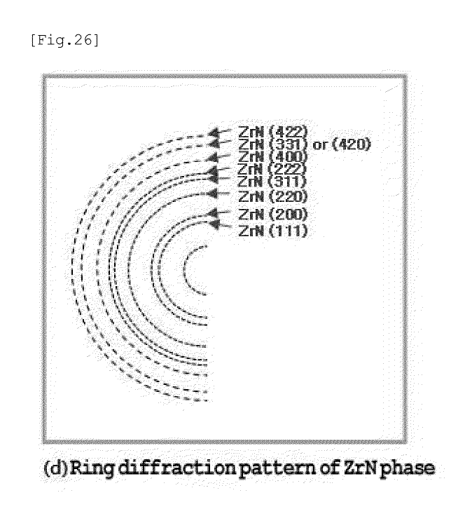

FIGS. 23 to 26 show the results of the SAD pattern of the films shown in FIGS. 20 to 22. As can be seen therein, the reactive sputtering film showed the typical diffuse halo pattern of an amorphous structure, and the reactive sputtering film appeared as a clear ring pattern, crystallization by the nitrification reaction occurred. In addition, as DC power increased to 350 W, a ZrN ring pattern was clearly observed.

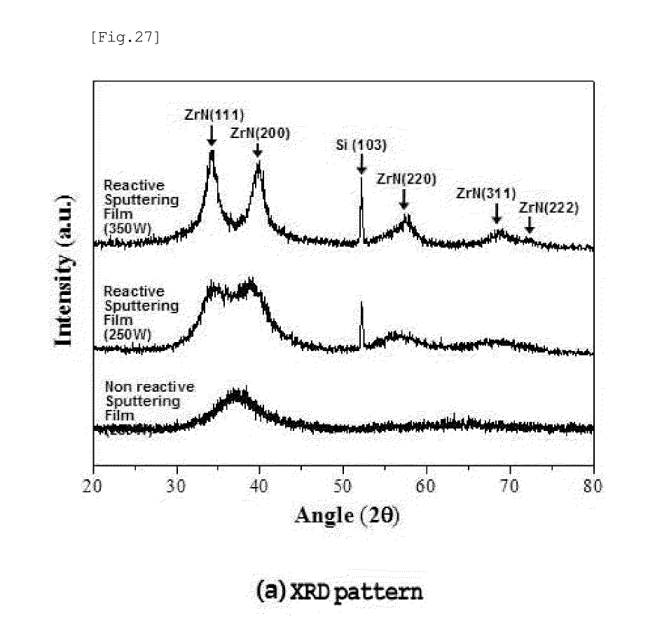

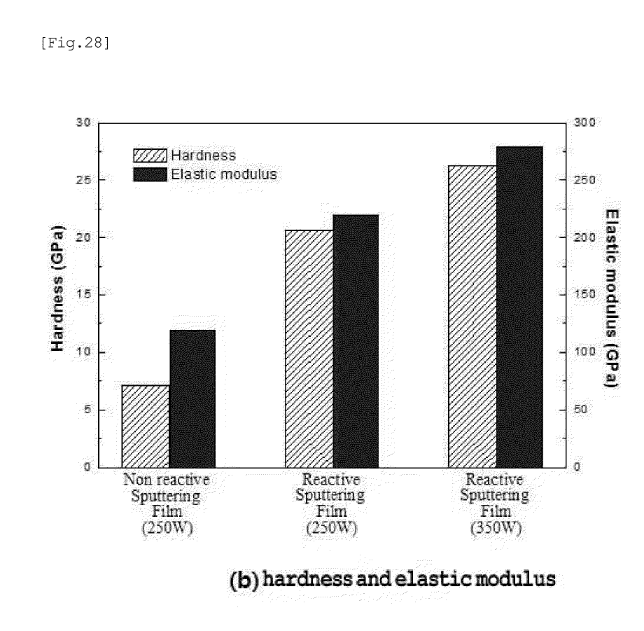

FIGS. 27 and 28 show the results of analysis of XRD diffraction patterns as a function of DC power. As can be seen therein, in the case of reactive sputtering films, the crystalline peal of the ZrN phase increased as DC power increased, and such results were consistent with the results of analysis of TEM SAD patterns shown in FIGS. 23 to 26. In addition, the reactive sputtering films had significantly increased hardness and elastic modulus compared to the non-reactive sputtering amorphous films (amorphous film: H=7 GPa, E=119; 250 W nitride film: H=20.6 GPa, E=252.7; 350 W nitride film: H=26.3 GPa, E=267.7). Furthermore, the H/E value was about 0.06 for the amorphous film and about 0.1 for the reactive sputtering film.

When the results of examining the structure and crystallization behavior of films deposited under various sputtering deposition conditions are put together, it can be seen that nano-sized ZrN crystals are incorporated into the amorphous base phase by reactive sputtering of nitrogen gas, and a nanostructured composite film composed of a nano-sized nitride crystalline phase and an amorphous phase is obtained. In addition, as plasma power in reactive sputtering increases from 250 W to 350 W, the fraction of nano-sized nitride crystalline phase further increases, thereby obtaining the crystalline film having a high H/E ratio of 0.1 and a hardness 3-4 times higher than that of the amorphous film.

[Formation of Thick Film and Examination of Depth Profile of Elements by GDOES Analysis]

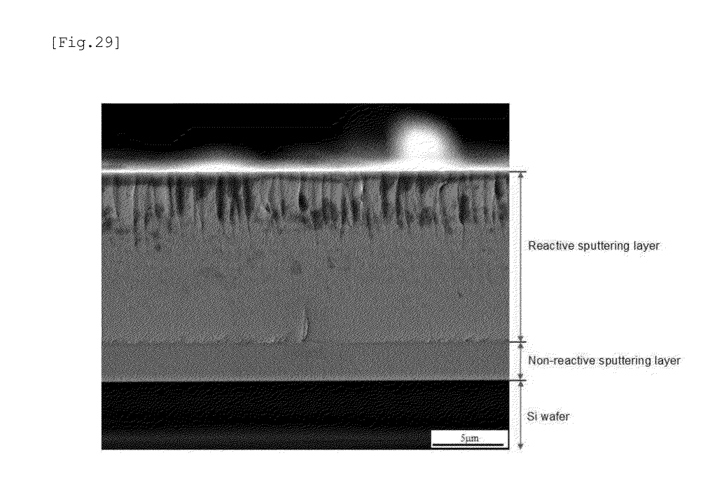

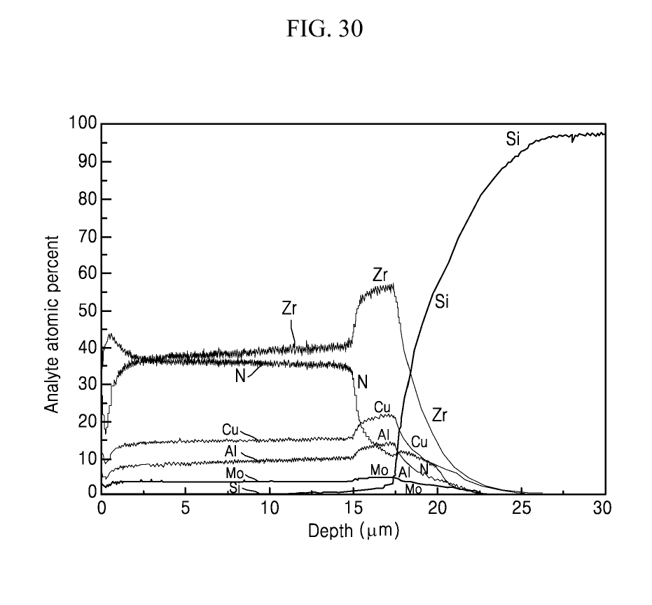

In the present invention, a thick film was formed to a thickness of 10 μm or more by a reactive sputtering process using a multi-component parent target material having a composition of example 3 (Zr_{62.5}Al₁₀Mo₅Cu_{22.5}). As the base layer of the thick film, an amorphous film was formed by non-reactive sputtering using the same target. FIG. 29 shows an FE-SEM photograph of the fracture surface of a thick film deposited for 4 hours. The surface hardness of the thick film was 20 GPa which was slightly lower the hardness of the thin film (22 GPa). The depth profile of each of target elements including nitrogen in a region ranging from the top surface of the thick film to the substrate portion was measured, and the results of the measurement are shown in FIG. 30.

Up to a depth of about 3 μm from the top surface of the thick film, the concentration of the nitrogen element was high and the concentration of the target elements was low. As the depth increases, the constituent elements of the layer formed earlier shows a relatively steady and uniform concentration distribution. The nitride forming elements, Zr and Al, show a concentration gradient which continuously increases as the depth increases, although the amounts thereof are very low. Also, the concentration of the nitrogen element shows a tendency to decrease as the concentrations of the nitride forming elements increase. This phenomenon is because the deposition temperature increases as a result of exposure to ion bombardment for a long time during the formation of a thick film having 10 μm or more. This phenomenon does not appear when a thin film having a thickness of 10 μm or less is formed.

However, the increase or decrease in the amount of each of the elements was 3 at % or less, which was very insignificant, and each of the elements showed a steady state concentration profile in the thickness direction of the film. In this uniform concentration region, the average concentration of nitrogen was about 32 at %. As the depth reached about 15 μm, the concentration of the nitrogen element rapidly decreased, whereas the concentrations of the other components rapidly increased. This discontinuous concentration profiles suggest that this depth is a position from which the amorphous intermediate layer starts and at which the reactive sputtering layer is ended. The intermediate layer had a very low concentration of the nitrogen element compared to the nitride layer, in which the nitrogen concentration was about 7-8 at % which was not negligible. In other words, this area contained some nitrogen, even though it was an intermediate buffer layer formed by non-reactive sputtering. This is believed to be because the formed film was exposed to ion bombardment for a long time of 4 hours (during which the thick film was formed), and thus the deposition temperature increased, whereby the nitrogen atom diffused into the non-nitride layer.

Generally, the need to form this thick film is very low. This test was carried out in order to examine the concentration gradient of elements in the formed thick film, thereby indirectly evaluating the stability and reproducibility of the concentration gradient of elements in a thin film. From the results of GDOES analysis of the formed thick film, it can be concluded that the use of a glass-forming alloy as a parent material enables the formation of a hard film in which the concentrations of elements are very steady.

Table 3 below shows the results of EPMA performed to examine the quantitative compositions of a raw material powder, a sintered sputtering target, a non-reactive thin film layer and a reactive thin film layer. The compositions of the raw material powder and the target showed a difference of less than 1 at % therebetween, and the non-reactive sputtering film showed a composition almost similar to the compositions of the powder and the target. In addition, the reactive sputtering film contained about 38 at % of nitrogen, and thus the atomic fraction of the target elements therein decreased. The results of detecting only four target elements without detecting the nitrogen element are expressed in parentheses in Table 3. It can be seen that the atomic ratio between the target elements showed a slight difference from that of the raw material of the target. Thus, from the results of the above EPMA and GDOES, it can be seen that the composition of the reactive sputtering film formed from the multi-component glass-forming alloy-based single target is almost similar to that of the multi-component target alloy and shows a uniform concentration distribution.

TABLE 3

| Nominal alloy | | Element concentration (at %) | | | | |
|---|---|---|---|---|---|---|
| composition | Sample | Zr | Cu | Al | Mo | N |
| Zr_{62.5}Al₁₀Mo₅Cu_{22.5} | Gas atomized | 62.89 | 21.67 | 10.26 | 4.18 | — |
| | powder | | | | | |
| | Sintered target | 63.11 | 22.58 | 10.02 | 4.29 | — |
| | Non-reactive | Power: 250 W | 62.94 | 22.57 | 10.24 | 4.24 |
| | sputtering film | | | | | |
| | Reactive | 250 W | 34.66 (57.98) | 12.84 (21.83) | 8.42 (14.13) | 3.61 (6.06) |
| | sputtering film; | 300 W | 38.45 (62.39) | 12.28 (19.97) | 7.30 (11.73) | 3.64 (5.90) |
| | gas mixing | 350 W | 38.70 (61.95) | 12.75 (20.39) | 7.13 (11.59) | 3.78 (5.07) |
| | ratio: 8:1 | | | | | |

* Parentheses indicate the content of elements in the reactive sputtering film.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

### INDUSTRIAL APPLICABILITY

As described above, the sputtering target of the present invention can form a uniform nanostructured thin film without a difference in sputtering yield between the elements by eliminating the segregation of the elements and maximizing the chemical homogeneity of the elements. In addition, the present invention can diversify the chemical complexity of a target material, and thus can provide a method of realizing a high-density nanostructured thin film having high structural complexity and dense atomic packing. Moreover, the present invention can provide a nano-composite coating film, which comprises a mixture of an active metal nitride (AMeN) and a soft metal (SMe) and has low friction and high hardness properties, using a single target through a selective reactive sputtering process. Furthermore, the present invention can provide a novel coating method which can be applied in future to a systematic design of low-friction/high-hardness thin films and the development of film formation technology.

1. (canceled)

2. (canceled)

3. (canceled)

4. (canceled)

5. (canceled)

6. A method for preparing a sputtering target of a multi-component single body, the method comprising forming an amorphous or partially crystallized glass-forming alloy system from a nitride forming metal element and a non-nitride forming element which has no or low solid solubility in the nitride forming metal element and does not react with nitrogen or has low reactivity with nitrogen, wherein the nitrogen forming metal element comprises at least one element selected from Ti, Zr, Hf, V, Nb, Ta, Cr, Y, Mo, W, Al, and Si, and the non-nitride forming element comprises at least one element selected from Mg, Ca, Sc, Ni, Cu, Ag, In, Sn, La, Au, and Pb.

7. The method of claim 6, wherein the nitride forming metal element is contained at an atomic ratio of 40-80 at %.

8. The method of claim 7, wherein the nitride forming metal element is contained at an atomic ratio of 60-80 at %.

9. The method of claim 6, wherein the sputtering target comprises at least one low-melting-point oxide forming element selected from Mo, V, Co, Ag, Cu, Ni, Ti, and W, which is capable of forming a low-friction oxide by a tribo-chemical reaction.

10. The method of claim 6, comprising atomizing the alloy comprising the nitride forming metal element and the non-nitride forming element, and heating, pressurizing and sintering the atomized powder in a supercooled liquid region, thereby forming a bulk alloy.

11. The method of claim 6, comprising performing a direct casting method in which the nitride forming metal element and the non-nitride forming metal element are melted and rapidly solidified, thereby forming a bulk alloy.

12. The method of claim 6, comprising crystallizing the nitride forming metal element and the non-nitride forming metal element by rapid solidification using a induction-cold crucible, and making the crystallized metal elements into a cast structure having a fine crystal, thereby forming a bulk alloy.

13. A method for fabricating a multi-component alloy-based nanostructured thin film, the method comprising:
preparing a target of an amorphous or partially crystallized glass-forming alloy system from a nitride forming metal element and a non-nitride forming metal element which does not react with nitrogen, and
subjecting the target to selective reactive sputtering in a mixed gas atmosphere comprising nitrogen and inert gas, thereby forming a thin film on a substrate,
wherein the nitrogen forming metal element comprises at least one element selected from Ti, Zr, Hf, V, Nb, Ta, Cr, Y, Mo, W, Al, and Si, and the non-nitride forming element comprises at least one element selected from Mg, Ca, Sc, Ni, Cu, Ag, In, Sn, La, Au, and Pb.

14. The method of claim 13, wherein the nitride forming metal element is contained at an atomic ratio of 40-80 at %.

15. The method of claim 14, wherein the nitride forming metal element is contained at an atomic ratio of 60-80 at %.

16. The method of claim 13, wherein the mixed gas for sputtering further comprises at least one reactive gas selected from an oxygen/oxide gas and a carbon/carbide gas.

17. The method of claim 13, wherein the target comprises at least one low-melting-point oxide forming element selected from Mo, V, Co, Ag, Cu, Ni, Ti, and W, which is capable of forming a low-friction oxide by a tribo-chemical reaction.

18. The method of claim 13, wherein the target is prepared by atomizing the nitride forming metal element and the non-nitride forming element, and heating, pressurizing and sintering the atomized powder in a supercooled liquid region, thereby forming a bulk alloy.

19. The method of claim 13, wherein an amorphous buffer layer resulting from non-reactive sputtering is formed between the substrate and the thin film formed by reactive sputtering.
